(19) United States
(12) Patent Application Publication
(10) Pub. No.: US 2026/0313806 A1
(43) Pub. Date: Oct. 8, 2026

(54) TOOLLESS LOCKING MEMBER AND ELECTRONIC SYSTEM COMPRISING THE SAME

(71) Applicant: Amphenol Commercial Products (Chengdu) Co., Ltd., Chengdu (CN)

(72) Inventors: Yongjia Xia, Chengdu (CN); Zhenfeng Lv, Chengdu (CN); Conglin Zhao, Chengdu (CN)

(73) Assignee: Amphenol Commercial Products (Chengdu) Co., Ltd., Chengdu (CN)

(21) Appl. No.: 19/640,957

(22) Filed: Apr. 7, 2026

(30) Foreign Application Priority Data
Apr. 8, 2025 (CN) 202510435897.9
Apr. 8, 2025 (CN) 202520653632.1

(51) Int. Cl. H05K 1/181

(52) U.S. Cl. CPC H05K 1/181; H05K 2201/10159; H05K 2201/10393

(57) ABSTRACT

Toolless locking member and electronic system comprising the locking member. An electronic system includes first and second substrates connected via a connector disposed therebetween. A locking member is configured to secure the first substrate to the second substrate. In some embodiments, the locking member includes a cover rotatable about a base, and a beam fixedly coupled to the cover at a selected location. The beam includes protrusions movable about the cover and configured to engage the first substrate. In some embodiments, the locking member includes a pawl rotatable about a positioner, and an elastic member coupling the pawl to the positioner. The positioner can engage the second substate. The pawl can engage the first substrate or a component disposed on the first substate, thereby securing the substrates together. Techniques described herein enables securing the substrates without the use of tools and can be compatible with configurations that include heat sinks.

### CROSS-REFERENCE TO RELATED APPLICATIONS

This application claims priority to and the benefit of Chinese Patent Application No. 202520653632.1, filed on Apr. 8, 2025. This application also claims priority to and the benefit of Chinese Patent Application No. 202510435897.9, filed on Apr. 8, 2025. The contents of these applications are incorporated herein by reference in their entirety.

### TECHNICAL FIELD

This application relates generally to electronic systems, such as those including electrical connectors, used to interconnect electronic assemblies.

### BACKGROUND

Compression Attached Memory Modules (CAMMs) are memory module designs that may be used in compact devices, such as laptops and workstations. A connector may be used to electrically connect a CAMM and a substrate such as a printed circuit board. Conventionally, screws are used to hold the CAMM, the connector, and the printed circuit board together.

### SUMMARY

Aspects of the present disclosure relate to toolless locking members and electronic systems comprising the same.

Some embodiments relate to a locking member configured for toolless securing a first substrate to a second substrate. The locking member may comprise a supporting base configured to engage the second substrate; a conductive cover rotatably coupled to the supporting base; and a conductive beam comprising a plurality of protrusions configured to engage the first substrate, the plurality of protrusions comprising a first protrusion fixedly connected to the conductive cover and a second protrusion movable relative to the conductive cover.

Optionally, the first protrusion of the conductive beam protrudes from a lower surface of the conductive beam; the conductive beam comprises a pair of grooves on an upper surface of the conductive beam facing away from the first protrusion, and a spacer between the pair of grooves; the conductive cover comprises a pair of lugs disposed in the pair of grooves of the conductive beam; and a connecting shaft extends through the pair of lugs of the conductive cover and the spacer of the conductive beam so as to fixedly connect the first protrusion to the conductive cover.

Optionally, the conductive cover is configured to rotate about the supporting base until the first protrusion and the second protrusion of the plurality of protrusions are disposed in corresponding positioning holes of the first substrate.

Optionally, the plurality of protrusions comprise at least two second protrusions on opposite sides of the first protrusion in a length direction of the conductive beam.

Optionally, the at least two second protrusions are symmetrically disposed on the opposite sides of the first protrusion.

Optionally, the first protrusion is located at a central portion of the conductive beam in the length direction of the conductive beam.

Optionally, the supporting base is a first supporting base; and the locking member comprises a second supporting base configured to engage the second substrate at an other end of the conductive cover, and a fastener configured to extend through the second substrate, the second supporting base, and the conductive cover at the other end of the conductive cover.

Optionally, the first substrate is a compression attached memory module (CAMM).

Some embodiments relate to a locking member configured for toolless securing a first substrate to a second substrate. The locking member may comprise a positioner configured to engage the second substrate; a pawl configured to engage the first substrate; and an elastic member configured to couple the pawl to the positioner.

Optionally, the locking member comprises a fastener comprising a head engaging the pawl, a distal end configured to secure to the second substrate, and a shank between the head and the distal end, the shank configured to extend through the pawl, the elastic member, and the positioner.

Optionally, the positioner is configured to be positioned adjacent to an end of the first substrate in a length direction of the first substrate.

Optionally, the positioner comprises a hollow portion, and a seat; the elastic member is disposed on the seat in the hollow portion; and the pawl is disposed on the elastic member.

Optionally, the pawl comprises a first portion having a long side subportion and a short side subportion, and a second portion extending from the long side subportion of the first portion into the hollow portion of the positioner and configured to engage the elastic member, the short side subportion of the first portion configured to press the first substrate.

Optionally, the short side subportion of the first portion is configured to engage a heat sink disposed on the first substrate.

Optionally, the fastener is configured to cooperate with the elastic member so as to adjust a distance between the long side subportion of the first portion of the pawl and the positioner opposite to a first end as well as a distance between the short side subportion of the first portion of the pawl and the second substrate.

Optionally, the positioner comprises a positioning slot; the second portion of the pawl comprises an extension protruding in a radial direction; and the pawl is configured to rotate about the positioner until the extension of the second portion of the pawl is inserted into the positioning slot of the positioner.

Optionally, the positioner comprises a convex portion adjacent to the positioning slot and protruding toward the pawl so as to restrain an extent of rotation of the pawl.

Some embodiments relate to an electronic system. The electronic system may comprise the locking member described herein; the first substrate; the second substrate; and a connector disposed between and connecting the first substrate and the second substrate.

Optionally, the first substrate is a compression attached memory module (CAMM).

Optionally, the electronic system comprises a backplate attached to the second substrate on a surface opposite the locking member.

Some embodiments relate to a locking member configured for toolless securing a first substrate to a second substrate, the first substrate configured to be disposed above the second substrate. The locking member may comprise a first supporting base configured to engage the second substrate; a conductive cover rotatably coupled to the first supporting base; and a conductive beam comprising a plurality of protrusions configured to engage the first substrate. At least one first protrusion of the plurality of protrusions may be fixedly connected to the conductive cover and at least one second protrusion of the plurality of protrusions may be movable relative to the conductive cover.

Optionally, the locking member comprises a fastener; the first supporting base is disposed in a length direction of the second substrate so as to be adjacent to one end of the first substrate in a length direction; and when the fastener extends through a connecting hole located in a first end in a length direction of the conductive cover and is pressed toward the second substrate, an opposite second end of the conductive cover rotates around a rotation shaft relative to the first supporting base, so that the first protrusions and the second protrusions of the plurality of protrusions are positioned in corresponding first positioning holes of the first substrate.

Optionally, the locking member comprises a second supporting base and a fastener; the second supporting base is configured to engage the second substrate; the first supporting base and the second supporting base are disposed along a length direction of the second substrate to be adjacent to two ends of the first substrate in the length direction; and when the fastener extends through a connecting hole located in a first end in a length direction of the conductive cover and is pressed toward the second supporting base engaged to the second substrate, an opposite second end of the conductive cover rotates around a rotation shaft relative to the first supporting base, so that the first end of the conductive cover is connected to the second supporting base through the fastener, and the first protrusions and the second protrusions of the plurality of protrusions are positioned in corresponding first positioning holes of the first substrate.

Optionally, the plurality of protrusions comprise at least two second protrusions located on both sides of the at least one first protrusion along a length direction of the conductive beam.

Optionally, the at least two second protrusions are symmetrically disposed on both sides of the at least one first protrusion along the length direction of the conductive beam.

Optionally, the at least one first protrusion is located at a central portion of the conductive beam in the length direction of the conductive beam.

Optionally, the at least one first protrusion of the plurality of protrusions is located at a central portion of the conductive beam in the length direction of the conductive beam; and the at least two second protrusions of the plurality of protrusions are symmetrically disposed on both sides of the at least one first protrusion along the length direction of the conductive beam.

Optionally, shape and size of a first protrusion of the plurality of protrusions are the same as shape and size of a second protrusion.

Optionally, when the conductive cover engages the second substrate, each of the plurality of protrusions are simultaneously positioned in a corresponding first positioning hole of the first substrate.

Optionally, when the conductive cover engages the second supporting base, each of the plurality of protrusions can be simultaneously positioned in a corresponding first positioning hole of the first substrate.

Optionally, the fastener is a thumbscrew.

Optionally, the at least one first protrusion of the conductive beam protrudes from a lower surface of the conductive beam; the conductive beam comprises a pair of grooves on an upper surface of the conductive beam facing away from the at least one first protrusion; the conductive beam comprises a spacer between the pair of grooves; the conductive cover comprises a pair of lugs corresponding to the pair of grooves of the conductive beam, the pair of lugs spaced apart by a distance corresponding to the spacer; the pair of lugs are placed in the pair of grooves; the spacer is placed between the pair of lugs; and a connecting shaft extends through holes of the pair of lugs and hole of the spacer, thereby fixedly connecting the at least one first protrusion to the conductive cover.

Some embodiments relate to a locking member configured for toolless securing a first substrate to a second substrate. The locking member may comprise a positioner configured to engage the second substrate; a pawl configured to engage the first substrate; and an elastic member configured to couple the pawl to the positioner.

Optionally, the locking member comprises a fastener comprising a head engaging the pawl, and a shank extending through the pawl, the elastic member, and the positioner; a distal portion of the shank is threaded; and at least a portion of the distal portion is fastened to a corresponding threaded hole of the second substrate.

Optionally, the positioner is configured to engage the second substrate in a manner that the positioner is positioned adjacent to an end in a length direction of the first substrate along a length direction of the second substrate.

Optionally, the positioner comprises a hollow portion; a first end of the positioner comprises a seat; the elastic member is disposed on the seat in the hollow portion; and the pawl is disposed on the elastic member.

Optionally, the pawl comprises a bent first portion and a linearly extending second portion; the first portion is substantially L-shaped and comprises a long side subportion and a short side subportion; the second portion extends from the long side subportion of the first portion into the hollow portion of the positioner to abut the elastic member; and the short side subportion of the first portion is configured to press the first substrate.

Optionally, after the pawl is rotated toward the first substrate and positioned above the first substrate, the fastener is screwed, and the second portion of the pawl is pressed toward the second substrate against an elastic force of the elastic member, thereby adjusting a distance between a lower edge of the long side subportion of the first portion of the pawl and a second end of the positioner opposite to a first end as well as a distance between the short side subportion of the first portion of the pawl and the second substrate.

Optionally, the second end of the positioner comprises positioning slots which are opposite to each other in a circumferential direction, and one of the positioning slots faces one end in a length direction of the first substrate; the second portion of the pawl comprises opposite extensions protruding in a radial direction, and one of the extensions faces the one end of the first substrate in the length direction; and after the pawl is rotated toward the first substrate and positioned above the first substrate and the fastener is screwed, the extension is inserted into the positioning slot.

Optionally, the second end of the positioner comprises a convex portion adjacent to a positioning slot of the positioning slots facing the first substrate, the convex portion protruding toward the pawl; and when the pawl is rotated toward the first substrate and positioned above the first substrate, an extension of the extensions of the pawl that faces the first substrate makes contact with the convex portion, thereby limiting further rotation of the pawl.

Optionally, the fastener is a thumbscrew.

Some embodiments relate to an electronic system. The electronic system may comprise a first substrate comprising a plurality of first positioning holes; a second substrate comprising a plurality of second positioning holes, the first substrate located above the second substrate; a connector disposed between the first substrate and the second substrate, the connector connecting the first substrate and the second substrate; and a locking member described herein.

Optionally, the connector comprises an upper projection and a lower projection protruding from an upper surface and a lower surface of the connector respectively, the upper projection inserted into a portion of a corresponding first positioning hole of the first substrate, and the lower projection inserted into a corresponding second positioning hole of the second substrate, thereby connecting the first substrate to the second substrate.

Optionally, a backplate with a shielding device is attached to a lower surface of the second substrate.

Optionally, the shielding device is a Mylar sheet.

Optionally, each of the plurality of protrusions is inserted into a portion of a corresponding first positioning hole of the first substrate.

Optionally, the electronic system comprises a heat sink disposed on a top of the first substrate; and after the pawl is rotated toward the heat sink and positioned above the heat sink, the fastener is screwed so that the pawl engages the heat sink.

Optionally, the electronic system comprises a thermal pad disposed between the heat sink and the first substrate, the thermal pad connecting the heat sink and the first substrate.

These techniques may be used alone or in any suitable combination. The foregoing summary is provided by way of illustration and is not intended to be limiting.

### BRIEF DESCRIPTION OF THE DRAWINGS

The accompanying drawings may not be drawn to scale. In the drawings, each identical or nearly identical component that is illustrated in various figures may be represented by a like numeral. For purposes of clarity, not every component may be labeled in every drawing. In the drawings:

FIG. 1 is an exploded perspective view of an electronic system, according to some embodiments.

FIG. 2A is an elevation view of the electronic system of FIG. 1, showing a locking member in a locked state.

FIG. 2B is a cross-sectional view of the electronic system of FIG. 2A.

FIG. 3 is a perspective view of a conductive cover and a conductive beam of the locking member shown in FIG. 2A.

FIG. 4 is a bottom perspective view of the conductive beam shown in FIG. 3.

FIG. 5 is an elevation view of an electronic system, according to some embodiments, showing a locking member in a locked state.

FIG. 6 is an exploded perspective view of the electronic system of FIG. 5.

FIG. 7 is a cross-sectional view of the locking member shown in FIG. 5.

FIG. 8 is a perspective view of the locking member of FIG. 5.

FIG. 9 is another perspective view of the locking member of FIG. 5.

### DETAILED DESCRIPTION

The inventors have recognized and appreciated design techniques for efficiently assembling components of an electronic assembly with reduced risk of malfunction of the resulting assembly. In some examples, locking members may be used to secure substrates to each other, such as securing a CAMM to a circuit board, without requiring additional tools, thereby improving installation efficiency and reliability. Conventional designs often rely on direct screw fastening for installation, which typically requires tools and may introduce risks during assembly (e.g., screws may be dropped into an electronic enclosure). In addition, such approaches may be less suitable in configurations where components, such as heat sinks, are positioned over the substrates. Techniques described herein may enable securing the substrates without the use of tools and may be compatible with configurations that include heat sinks. Such techniques may provide sufficient compression when a heat sink is mounted above the substrates.

According to aspects of the present disclosure, a locking member may include a rotatable cover configured to be rotated to engage a substrate and secured in position using a fastening element. A beam may be disposed in a central region of the locking member and configured to distribute a downward force applied to the substrates. In some embodiments, the locking member may include a thumbscrew, thereby enabling fixation without requiring additional tools during installation. The rotatable cover may operate based on a lever principle to provide mechanical advantage and reduce installation force. The beam may operate in a manner similar to a seesaw mechanism to mitigate uneven pressure distribution that may arise from sequential force application at multiple contact points. The thumbscrew may be configured to apply a downward force to facilitate tool-free operation and adjustment.

The beam may include a plurality of protrusions, including a first protrusion configured as a fixed fulcrum and a second protrusion located closer to a first supporting base. The first protrusion may be fixed relative to a conductive cover, while the second protrusion may be movable relative to the conductive cover (e.g., rotatable about a connecting shaft). In operation, the second protrusion may contact a first substrate and remain in contact while permitting relative movement, thereby limiting the magnitude of interaction force between the second protrusion and the first substrate. In the context of the present disclosure, a “limited interaction force” may refer to a force that is insufficient to cause functional degradation or adverse effects in the first substrate due to uneven stress. Because the second protrusion is movable relative to the conductive cover, the interaction force applied at the second protrusion may remain relatively small while maintaining contact. As a result, the plurality of protrusions of the beam may collectively operate in a manner analogous to a seesaw, thereby reducing or avoiding uneven force distribution on the first substrate that could otherwise result from sequential engagement of the protrusions with corresponding positioning features of the substrate.

According to aspects of the present disclosure, a locking member may include a pawl configured for use in configurations where one or more components (such as heat sinks) are mounted above one or more substrates. The pawl may be configured to transition between an unlocked state and a locked state, for example, by rotation of the pawl and securement with a fastener to apply a downward force.

In some embodiments, the locking member may include a positioner configured to engage a substrate, and an elastic member configured to couple the pawl to the positioner. The elastic member may enable adjustable height and controlled downward travel of the pawl relative to the substrate, for example, in conjunction with a thumbscrew.

Next, example embodiments according to the present disclosure will be described in detail with reference to the accompanying drawings. It is to be understood that orientation or positional relations indicated by terms such as “above” and “below” may be based on the orientation or positional relations as shown in the figures, only for facilitating description of the present disclosure and simplifying the description, rather than indicating or implying that the referred devices or elements must be in a particular orientation or configured or operated in the particular orientation, and therefore they may not be construed as limiting the present disclosure.

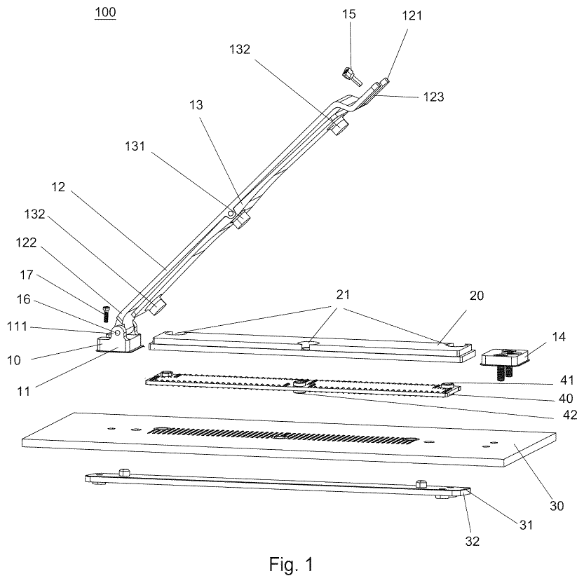

One aspect of the present disclosure provides a locking member 10 configured for toolless mounting a first substrate 20 to a second substrate 30. Referring to FIGS. 1 to 4, in some embodiments, the locking member 10 comprises: a first supporting base 11 configured to engage the second substrate 30, a conductive cover 12 configured to be rotatably coupled to the first supporting base 11, and a conductive beam 13 comprising a plurality of protrusions to engage the first substrate 20. At least one first protrusion 131 of the plurality of protrusions may be fixedly connected to the conductive cover 12 and at least one second protrusion 132 of the plurality of protrusions may be movable relative to the conductive cover 12.

In some embodiments, the locking member comprises a fastener 15. The first substrate 20 is configured to be disposed above the second substrate 30. The first supporting base 11 is disposed in a length direction of the second substrate 30 to be adjacent to one end of the first substrate 20 in a length direction. In the illustrated example, when the fastener 15 extends through a connecting hole 123 located in a first end 121 in a length direction of the conductive cover 12 and is pressed toward the second substrate 30, an opposite second end 122 of the conductive cover 12 rotates around a rotation shaft 16 relative to the first supporting base 11 until the first end 121 of the conductive cover 12 engages the second substrate 30, so that the first protrusion 131 and the second protrusion 132 of the plurality of protrusions are positioned in corresponding first positioning holes 21 of the first substrate 20. In this way, the locking member 10 utilizes the principle of leverage to reduce the force required to be applied to the conductive cover 12, thereby improving the efficiency of mounting the first substrate 20 to the second substrate 30.

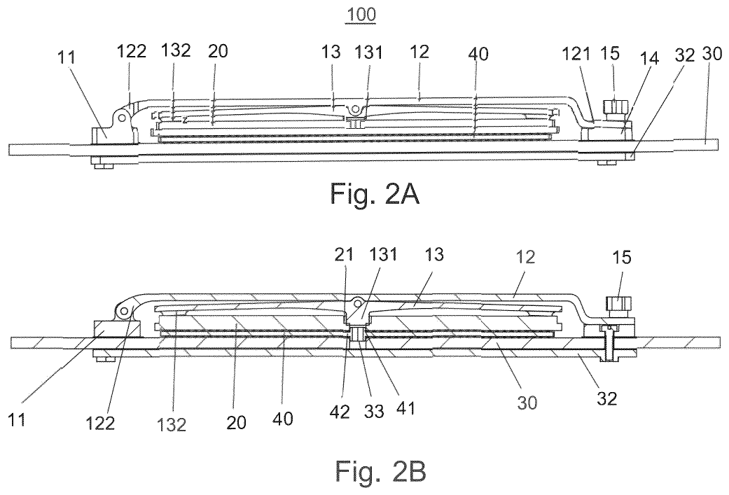

In some embodiments, referring to FIGS. 1, 2A, and 2B, the locking member 10 comprises a second supporting base 14 configured to engage the second substrate 30 and a fastener 15. When the fastener 15 extends through a connecting hole 123 located in a first end 121 in a length direction of the conductive cover 1 and is pressed toward the second supporting base 14 engaged to the second substrate 30, an opposite second end 122 of the conductive cover 12 rotates around a rotation shaft 16 relative to the first supporting base 11, so that the first end 121 of the conductive cover 12 is connected to the second supporting base 14 through the fastener 15, and the first protrusion 131 and the second protrusion 132 of the plurality of protrusions are positioned in corresponding first positioning holes 21 of the first substrate 20, and in particular, each of the plurality of protrusions is positioned substantially simultaneously (for example, a large portion of each protrusion is pressed into or each protrusion is completely pressed into) corresponding first positioning holes 21 of the first substrate 20. For example, the plurality of protrusions may be mostly or completely pressed into corresponding first positioning holes substantially at the same time.

In some embodiments, referring to FIGS. 1, 2A, and 2B, the first substrate 20 is configured to be disposed above the second substrate 30. The first supporting base 11 and the second supporting base 14 are disposed in a length direction of the second substrate 30 to be adjacent to both ends of the first substrate 20 in the length direction.

In some embodiments, when the first substrate 20 needs to be mounted to the second substrate 30, both of the first supporting base 11 and the second supporting base 14 are engaged to the second substrate 30, and the fastener 15 extends through the connecting hole 123 in the first end 121 of the conductive cover 12 and is pressed toward the second supporting base 14. In this case, the second end 122 of the conductive cover 12 rotates around the rotation shaft 16 relative to the first supporting base 11 until the first end 121 of the conductive cover 12 is connected to the second supporting base 14 through the fastener 15, so that the first protrusion 131 and the second protrusion 132 of the plurality of protrusions are inserted into corresponding first positioning holes 21 of the first substrate 20. For example, the conductive cover 12 is rotated around the rotation shaft 16 relative to the first supporting base 11 by pressing the first end 121 of the conductive cover 12 through the fastener 15 until the conductive cover 12 engages the second supporting base 14. In this way, the locking member 10 utilizes the principle of leverage to reduce the force required to be applied to the conductive cover 12, thereby improving the efficiency of mounting the first substrate 20 to the second substrate 30.

In some embodiments, as shown in FIGS. 1, 2A, and 2B, the first supporting base 11 is formed as a square block and comprises a pair of flanges 111 located at the top of the block, and the conductive cover 12 is rotatably coupled to the first supporting base 11 by a rotation shaft 16 extending through holes of the pair of flanges 111. In some examples, the first supporting base 11 may be formed in other shapes. For example, the first supporting base 11 may be formed in the form of a polygonal prism.

In some embodiments, as shown in FIGS. 1, 2A, and 2B, the first supporting base 11 is configured to engage the second substrate 30 by a fastener such as a screw 17. In some examples, the first supporting base 11 may also be configured to engage the second substrate 30 in other ways. For example, the first supporting base 11 may be configured to be welded to the second substrate 30.

In some embodiments, as shown in FIG. 1, the second supporting base 14 is configured to engage the second substrate 30 by a fastener such as a screw. In some examples, the second supporting base 14 may also be configured to engage the second substrate 30 in other ways. For example, the second supporting base 14 may be configured to be welded to the second substrate 30.

In some embodiments, the plurality of protrusions comprise at least two second protrusions 132 located on both sides of the at least one first protrusion 131 in a length direction of the conductive beam 13. In some embodiments, the at least two second protrusions 132 are substantially symmetrically disposed on both sides of at least one first protrusion 131 in the length direction of the conductive beam 13. In some embodiments, at least one first protrusion 131 is located at a central portion of the conductive beam 13 in a length direction of the conductive beam 13.

In some embodiments, at least one first protrusion 131 of the plurality of protrusions is located at a central portion of the conductive beam in the length direction of the conductive beam 13, and at least two second protrusions 132 of the plurality of protrusions are substantially symmetrically disposed on both sides of the at least one first protrusion along the length direction of the conductive beam 13.

In some embodiments, as shown in FIGS. 1 to 4, the plurality of protrusions are three protrusions, one first protrusion 131 of the three protrusions is located at a central portion of the conductive beam 13 in the length direction of the conductive beam 13, and the other two second protrusions 132 of the three protrusions are substantially symmetrically disposed on both sides of the first protrusion in the length direction of the conductive beam 13. It is understood that in some alternative embodiments, one first protrusion 131 with a larger size shown in FIGS. 1 to 4 may be replaced by, for example, two or more first protrusions 131 with smaller sizes. It can also be understood that in other alternative embodiments, the arrangement of one or more first protrusions 131 on the conductive beam 13 may be changed according to design requirements.

For example, in some examples, two or more first protrusions 131 may be disposed non-linearly (e.g., annularly or triangularly) at a substantially middle position of the conductive beam 13.

Furthermore, in the exemplary embodiment shown in FIGS. 1 to 4, the other two second protrusions 132 of the three protrusions are disposed to be located at two opposite ends of the conductive beam 13 in the length direction of the conductive beam 13, and the length of the conductive beam 13 corresponds to the length of the first substrate 20, so that after the plurality of protrusions are inserted into the corresponding first positioning holes 21 of the first substrate 20, the forces applied by the plurality of protrusions to the first substrate 20 are evenly distributed on the first substrate 20, so that the first substrate 20 can be stably mounted to the second substrate 30.

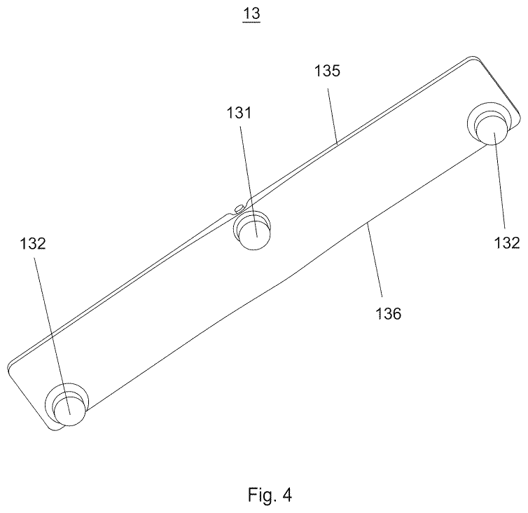

In some embodiments, as shown in FIG. 4, shape and size of the first protrusion 131 of the plurality of protrusions are the same as shape and size of the second protrusion 132. In this way, after the plurality of protrusions are inserted into corresponding first positioning holes 21 of the first substrate 20, the forces applied to the first substrate 20 are substantially the same.

However, it will be understood that in other embodiments, two or more first protrusions 131 may have different shapes and/or sizes; two or more second protrusions 132 may have different shapes and/or sizes; and/or, two or more first protrusions and second protrusions may have different shapes and/or sizes.

In some embodiments, as shown in FIG. 4, each of the plurality of protrusions is cylindrical. In some examples, the shape of each of the plurality of protrusions may be other shapes. For example, the shape of each of the plurality of protrusions may be a polygonal column.

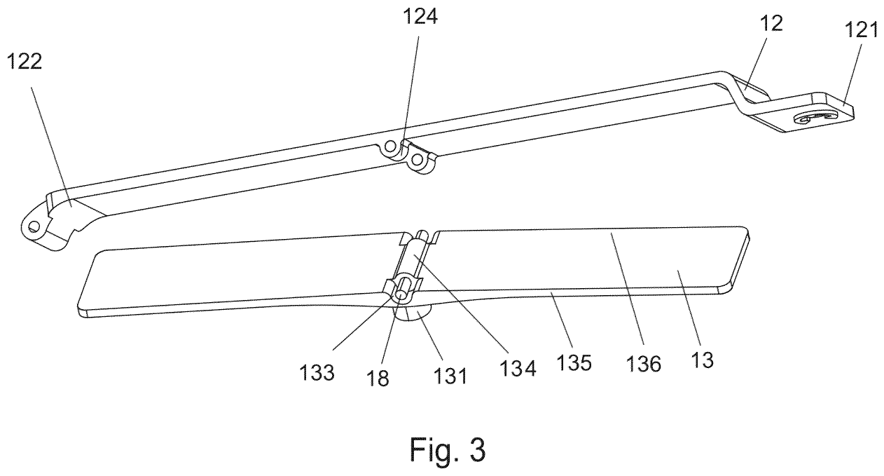

In some embodiments, as shown in FIG. 1, there is an angle between the second protrusion 132 of the conductive beam 13 and the conductive cover 12 due to the weight of the conductive beam 13 itself. When the conductive cover 12 and the conductive beam 13 rotate about the rotation shaft 16 relative to the first supporting base 11 toward the second substrate 30, the second protrusion 132 of the plurality of protrusions closest to the first supporting base 11 may first contact the first substrate 20. The second protrusion 132 is always kept in contact with the first substrate 20 in a process where the fastener 15 is continuously pressed toward the second supporting base 14 engaged to the second substrate 30 until the conductive cover 12 and the conductive beam 13 are parallel to the first substrate 20 and the first end 121 of the conductive cover 12 engages the second supporting base 14 through the fastener 15. Since the second protrusion 132 is movable relative to the conductive cover 12, in particular, since the second protrusion 132 can be rotated around the connecting shaft 18 (see FIG. 3) relative to the conductive cover 12, there is limited interaction force between the second protrusion 132 and the first substrate 20. Thereafter, the fastener 15 is screwed so that the first protrusion 131 and the second protrusion 132 are inserted into a portion of the corresponding first positioning hole 21 of the first substrate 20. In this way, the conductive beam 13 is fixedly connected to the first protrusion 131 of the conductive cover 12 so that: during the rotation of the conductive cover 12 and the conductive beam 13 around the rotation shaft 16 relative to the first supporting base 11 toward the second substrate 30, the second protrusion 132 of the conductive beam 13 close to the first supporting base 11 can first contact the first substrate 20 and thereafter always keep in contact with the first substrate 20. Since the second protrusion 132 is movable relative to the conductive cover 12, in particular, since the second protrusion 132 can be rotated around the connecting shaft 18 (see FIG. 3) relative to the conductive cover 12, there is limited interaction force between the second protrusion 132 and the first substrate 20, thereby avoiding the problem of uneven force caused by the first protrusion 131 and the second protrusion 132 pressed into the corresponding first positioning holes 21 of the first substrate 20 one after another.

With the above locking member provided by the present disclosure, at least one first protrusion 131 of the plurality of protrusions of the conductive beam 13 is used as a fixed fulcrum because it is fixedly connected to the conductive cover 12, and the second protrusion 132 can always keep in contact with the first substrate 20 after contacting the first substrate 20 and is movable relative to the conductive cover 12, in particular, can be rotated around the connecting shaft 18 (see FIG. 3) relative to the conductive cover 12, so that there is limited interaction force between the second protrusion 132 and the first substrate 20. Therefore, the plurality of protrusions of the conductive beam 13 work as a whole on a principle similar to a “seesaw”, thereby solving the problem of uneven force that may be present on the first substrate 20 caused by the first protrusion and the second protrusion of the plurality of protrusions pressed into the corresponding first positioning holes 21 of the first substrate 20 in sequence.

In the exemplary embodiment shown in FIGS. 1 to 4, in particular referring to FIG. 3, the first protrusion 131 and the second protrusion 132 of the conductive beam 13 protrude from a lower surface of the conductive beam 13; the conductive beam 13 comprises a pair of grooves 133 on an upper surface of the conductive beam 13 facing away from the at least one first protrusion 131; the conductive beam 13 comprises a spacer 134 between the pair of grooves 133; the conductive cover 12 comprises a pair of lugs 124 corresponding to the pair of grooves 133 of the conductive beam 13, the pair of lugs 124 spaced apart by a distance corresponding to the spacer 134; the pair of lugs 124 are placed in the pair of grooves 133; the spacer 134 is placed between the pair of lugs 124, and a connecting shaft 18 extends through holes of the pair of lugs 124 and holes of the spacer 134, thereby fixedly connecting the at least one first protrusion 131 to the conductive cover 12.

In some embodiments, as shown in FIG. 4, at least one first protrusion 131 of the plurality of protrusions of the conductive beam 13 protrudes from a lower surface at a central portion of the conductive beam 13 in a length direction at a position adjacent to first side portion 135 of the conductive beam 13 in a width direction, and the second protrusions 132 of the plurality of protrusions protrude from lower surface at both ends of the conductive beam 13 in the length direction at a second side portion 136 of the conductive beam 13 opposite to the first side portion 135, so that when the first protrusion 131 and the second protrusion 132 of the plurality of protrusions are respectively inserted into corresponding first positioning holes 21 of the first substrate 20 and are further pressed toward the first substrate 20, forces applied to the first substrate 20 by the first protrusion 131 and the second protrusion 132 of the plurality of protrusions form a stable triangular structure on the first substrate 20, so as to facilitate stable mounting of the first substrate 20 to the second substrate 30.

In some embodiments, the at least one first protrusion 131 of the conductive beam 13 may also be fixedly connected to the conductive cover 12 in other ways. For example, the at least one first protrusion 131 of the conductive beam 13 may be screwed to the conductive cover 12 by a screw.

In some embodiments, the fastener 15 may be a thumbscrew. In this way, the operator only needs to press the thumbscrew with a finger to press the first end 121 of the conductive cover 12 to rotate the conductive cover 12 around the rotation shaft 16 relative to the first supporting base 11, and then the conductive cover 12 can engage the second supporting base 14 and/or the second substrate 30, thereby further mounting the first substrate 20 to the second substrate 30 without any other additional tools. Furthermore, after positioning the plurality of protrusions of the conductive beam 13 in the corresponding first positioning holes 21 of the first substrate 20, the operator may adjust the force applied by the plurality of protrusions to the first substrate by screwing the thumbscrews, thereby achieving a good effect of mounting.

Another aspect of the present disclosure provides an electronic system 100. Referring to FIGS. 1 to 4, the electronic system 100 comprises: a first substrate 20 comprising a plurality of first positioning holes 21, a second substrate 30 comprising a plurality of second positioning holes 33, the first substrate 20 located above the second substrate 30, a connector 40 disposed between the first substrate 20 and the second substrate 30, the connector 40 connecting the first substrate 20 and the second substrate 30, and the locking member 10 described above with reference to FIGS. 1 to 4 and configured for toolless mounting the first substrate 20 to the second substrate 30.

In some examples, the first substrate may be, for example, a system-on-chip advanced memory module (SOCAMM). However, the present disclosure is not limited thereto. The second substrate may be, for example, a printed circuit board. However, the present disclosure is not limited thereto. The connector may be a SOCAMM connector. The connector is configured to connect two substrates, and the specific configuration of the connector may be as described in the previous US application US20240178592A1. However, the present disclosure is not limited thereto. According to the actual use of the product, the connector may have any other suitable structure as long as it can connect two substrates and meet the electrical and mechanical reliability requirements.

In some embodiments, as shown in FIGS. 1, 2A, and 2B, the connector 40 comprises a plurality of upper projections 41 and a plurality of lower projections 42 protruding from the upper surface and the lower surface of the connector, respectively; the upper projections 41 are inserted into a portion of the corresponding first positioning holes 21 of the first substrate 20, and the lower projections 42 are inserted into the corresponding second positioning holes 33 of the second substrate 30, thereby connecting the first substrate 20 to the second substrate 30, and forming a reliable mechanical connection and electrical connection between the first substrate 20 and the second substrate 30.

In some embodiments, as shown in FIG. 1, a backplate 32 with a shielding device 31 is attached to the lower surface of the second substrate 30. The shielding device is used to prevent the light inside the electronic device from leaking to the outside. In some embodiments, the shielding device is a Mylar sheet. In some example embodiments, the mylar sheet is formed from a polycarbonate film or a polyethylene terephthalate (PET) film. In some examples, the mylar sheet is characterized by dimensional stability as well as tearing-resistant strength. Thus, in some example embodiments of the present disclosure, the mylar sheet does not readily deform during assembly. In some embodiments, the Mylar sheet can be directly attached to the lower surface of the second substrate due to its own adhesiveness. Therefore, in the process of assembling the Mylar sheet to the second substrate, no other adhesive is needed, thereby shortening the assembly time.

According to the electronic system 100 provided in the present disclosure, the first supporting base 11 and the second supporting base 14 of the locking member 10 are engaged to the upper surface of the second substrate 30 in the length direction of the second substrate 30 and are positioned adjacent to both ends of the first substrate 20 in the length direction. When the fastener 15 extending through the connecting hole 123 of the first end 121 of the conductive cover 12 is pressed toward the second supporting base 14, the second end 122 of the conductive cover 12 is rotated around the rotation shaft 16 relative to the first supporting base 11 until the first end 121 of the conductive cover 12 is connected to the second supporting base 14 through the fastener 15, and the fastener 15 is screwed so that the first protrusion 131 and the second protrusion 132 of the plurality of protrusions of the conductive beam 13 are inserted into a portion of the corresponding first positioning holes 21 of the first substrate 20. In this way, with the fastener 15 pressing the first end 121 of the conductive cover 12 to rotate the conductive cover 12 around the rotation shaft 16 relative to the first supporting base 11, the locking member 10 uses the lever principle of the conductive cover 12 to reduce the force applied to the conductive cover 12, thereby improving efficiency. Furthermore, without using additional tools, the operator only needs to operate the fasteners of the locking member 10 to securely connect and mount the first substrate 20 to the second substrate 30.

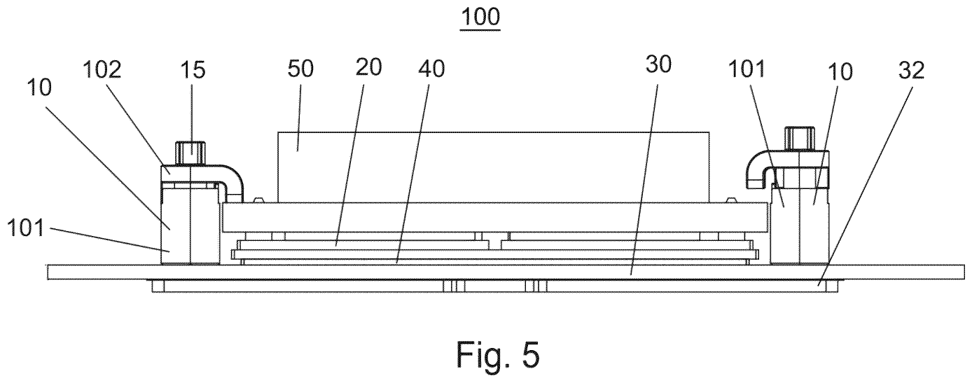

Another aspect of the present disclosure provides a locking member 10. Referring to FIGS. 5 to 9, the locking member 10 is configured for toolless mounting the first substrate 20 to the second substrate 30. The locking member 10 comprises a positioner 101 configured to engage the second substrate 30, a pawl 102 configured to engage the first substrate 20, and an elastic member 103 configured to couple the pawl 102 to the positioner 101.

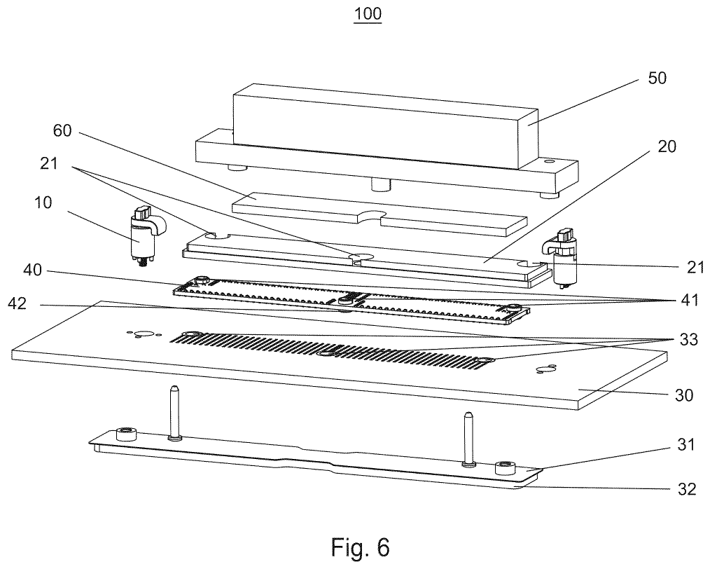

In some embodiments, as shown in FIGS. 5 and 6, a heat sink 50 is mounted on the first substrate 20 to dissipate heat from the first substrate 20 and/or the second substrate 30. As such, in the exemplary embodiment shown in FIGS. 5 and 6, the pawl 102 is configured to engage the heat sink 50. For example, the pawl 102 is configured to be indirectly engaged to the first substrate 20. However, the present disclosure is not limited thereto, and in some examples, the pawl 102 may be configured to be directly engaged to the first substrate 20. In some examples, the elastic member 103 may be a spring, such as a coil spring. However, the present disclosure is not limited thereto. In some examples, the elastic member 103 may be a rubber element having elasticity.

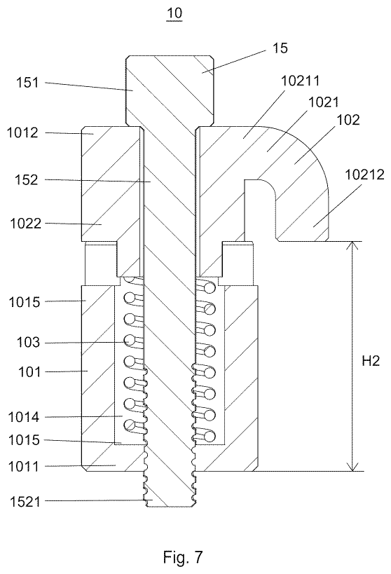

In some embodiments, as shown in FIGS. 7 to 9, the locking member 10 comprises a fastener 15 comprising a head 151 engaging with the pawl 102 and a shank 152 extending through the pawl 102, the elastic member 103 and the positioner 101; a distal portion 1521 of the shank 152 is threaded, and at least a portion of the threaded distal portion 1521 is fastened to the corresponding threaded hole of the second substrate 30.

In some embodiments, after the pawl 102 is rotated toward the first substrate 20 and/or the heat sink 50 and positioned above the first substrate 20 or the heat sink 50, the fastener 15 is screwed so that the pawl 102 engages the first substrate 20 or the heat sink 50, and the first substrate 20 is pressed toward the second substrate 30 through the fastener 15, thereby mounting the first substrate 20 to the second substrate 30.

In some embodiments, as shown in FIGS. 5 and 6, the positioner 101 is configured to engage the second substrate 30 in a manner that the positioner 101 is positioned adjacent to an end in the length direction of the first substrate 20 along the length direction of the second substrate 30. In some embodiments, as shown in FIGS. 7 to 9, the positioner 101 comprises a first end 1011 and a second end 1012 opposite in the axial direction, and the first end 1011 comprises a plurality of projecting portions 1013 inserted into corresponding holes of the second substrate 30 to engage the positioner 101 to the second substrate 30. However, the present disclosure is not limited thereto. In some examples, the positioner 101 may engage the second substrate 30 in other ways. For example, the positioner 101 may be welded to the second substrate 30.

In some embodiments, as shown in FIG. 7, the positioner 101 comprises a hollow portion 1014; a first end 1011 of the positioner 101 comprises a seat 1015; the elastic member 103 is disposed on the seat 1015 in the hollow portion 1014, and the pawl 102 is disposed on the elastic member 103 and abuts against the elastic member 103, thereby connecting the pawl 102 to the positioner 101.

In some embodiments, as shown in FIG. 7, the pawl 102 comprises a bent first portion 1021 and a linearly extending second portion 1022; the first portion 1021 is formed into a substantially L-shaped form comprising a long side subportion 10211 and a short side subportion 10212; the second portion 1022 extends from the long side subportion 10211 of the first portion 1021 into the hollow portion 1014 of the positioner 101 to abut the elastic member 103, and the short side subportion 10212 of the first portion 1021 is configured to engage the first substrate 20 or the heat sink 50.

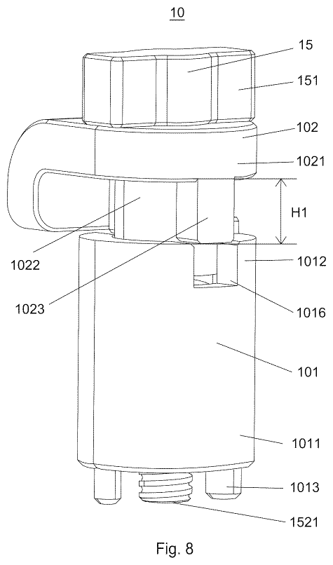

In some embodiments, after the pawl 102 is rotated toward the first substrate 20 and/or the heat sink 50 and positioned above the first substrate 20 or the heat sink 50, the fastener 15 is screwed so that the second portion 1022 of the pawl 102 is pressed toward the second substrate 30 against the elastic force of the elastic member 103, thereby adjusting a distance H1 (see FIG. 8) between a lower edge of the long side subportion 10211 of the first portion 1021 of the pawl 102 and the second end 1012 of the positioner and a distance H2 (see FIG. 7) between the short side subportion 10212 of the first portion 1021 of the pawl 102 and the second substrate 30.

In some examples, when the heat sink 50 is mounted on the first substrate 20, the head 151 of the fastener 15 is rotated by a smaller amplitude to adjust the distance H1 and the distance H2 at the same time, so that the short side subportion 10212 of the first portion 1021 of the pawl can engage the heat sink 50; when the heat sink 50 is not mounted on the first substrate 20, the head 151 of the fastener 15 is rotated by a larger amplitude to adjust the distance H1 and the distance H2 at the same time, so that the short side subportion 10212 of the first portion 1021 of the pawl can be directly engaged to the first substrate 20. In this way, the operator can conveniently adjust the component to be engaged by the pawl 102 according to the needs of the product, so as to accommodate different mounting requirements.

In some embodiments, as shown in FIG. 8, the second end 1012 of the positioner 101 comprises positioning slots 1016 which are opposite to each other in a circumferential direction, and one of the positioning slots 1016 faces one end in the length direction of the first substrate 20; the second portion 1022 of the pawl 102 comprises opposite extensions 1023 protruding in a radial direction, and one of the extensions 1023 faces the above-mentioned one end of the first substrate 20 in the length direction; after the pawl 102 is rotated toward the first substrate 20 and/or the heat sink 50 and is positioned above the first substrate 20 or the heat sink 50 and the fastener 15 is screwed, the extension 1023 is inserted into the positioning slot 1016. In this way, a precise positioning of the pawl 102 relative to the positioner 101 is provided, thereby making the operation of the locking member more precise.

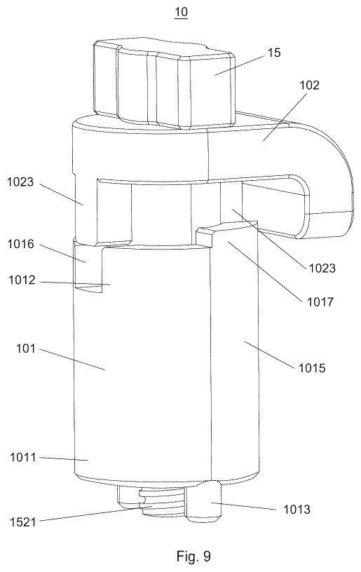

In some embodiments, as shown in FIG. 9, the second end 1012 of the positioner 101 comprises a convex portion 1017 adjacent to a positioning slot of the positioning slots 1016 facing the first substrate 20, the convex portion 1017 protruding toward the pawl 102; when the pawl 102 is rotated toward the first substrate 20 and/or the heat sink 50 and is positioned above the first substrate 20 or the heat sink 50, a extension of the extensions 1023 of the pawl 102 that faces the first substrate 20 contacts with the convex portion 1017, thereby limiting further rotation of the pawl 102.

In the exemplary embodiment shown in FIGS. 5 to 9, the fastener 15 may be a thumbscrew. In this way, the operator only needs to engage the pawl 102 to the first substrate 20 and/or the heat sink 50 by screwing the head of the thumbscrew after rotating the pawl 102 toward the first substrate 20 and/or the heat sink 50, thereby mounting the first substrate 20 to the second substrate 30 without any other additional tools.

Yet another aspect of the present disclosure provides an electronic system 100. The electronic system 100 comprises: a first substrate 20 comprising a plurality of first positioning holes 21; a second substrate 30 comprising a plurality of second positioning holes 33, the first substrate 20 located above the second substrate 30; a connector 40 disposed between the first substrate 20 and the second substrate 30, the connector 40 connecting the first substrate 20 and the second substrate 30; and the locking member 10 described above with reference to FIGS. 4 to 9 and configured for toolless mounting the first substrate 20 to the second substrate 30.

In some examples, the first substrate may be, for example, a System-On-Chip Attached Memory Module (SOCAMM). However, the present disclosure is not limited thereto. The second substrate may be, for example, a printed circuit board. However, the present disclosure is not limited thereto. The connector may be a SOCAMM connector. The connector is configured to connect two substrates, and the specific configuration of the connector may be as described in the previous US application US20240178592A1. However, the present disclosure is not limited thereto. According to the actual use of the product, the connector may have any other suitable structure as long as it can connect two substrates and meet the electrical and mechanical reliability requirements.

In some embodiments, a backplate 32 with a shielding device 31 is attached to the lower surface of the second substrate 30. The shielding device is used to prevent the light inside the electronic device from leaking to the outside. In some embodiments, the shielding device is a Mylar sheet. In some example embodiments, the mylar sheet is formed from a polycarbonate film or a polyethylene terephthalate (PET) film. In some examples, the mylar sheet is characterized by dimensional stability as well as tearing-resistant strength. Thus, in some example embodiments of the present disclosure, the mylar sheet does not readily deform during assembly. In some embodiments, the Mylar sheet can be directly attached to the lower surface of the second substrate due to its own adhesiveness. Therefore, in the process of assembling the Mylar sheet to the second substrate, no other adhesive is needed, thereby shortening the assembly time.

In some embodiments, the connector 40 comprises a plurality of upper projections 41 and a plurality of lower projections 42 protruding from the upper surface and the lower surface of the connector, respectively; the upper projections 41 are inserted into a portion of the corresponding first positioning holes 21 of the first substrate 20, and the lower projections 42 are inserted into the corresponding second positioning holes 33 of the second substrate 30, thereby connecting the first substrate 20 to the second substrate 30, and forming a reliable mechanical connection and electrical connection between the first substrate 20 and the second substrate 30.

In some embodiments, as shown in FIGS. 5 and 6, the positioner 101 of the locking member 10 engages the upper surface of the second substrate 30 in a manner that the positioner is positioned adjacent to the end of the first substrate 20 in the length direction of the second substrate 30. The heat sink 50 is disposed on the first substrate 20 and the thermal pad 60 is disposed between the heat sink 50 and the first substrate 20, and connects the heat sink 50 and the first substrate 20 to further improve the heat dissipation effect. The lower surface of the heat sink 50 comprises a plurality of protrusions, and the plurality of protrusions of the heat sink 50 are inserted into a portion of the corresponding first positioning holes 21 of the first substrate 20. After the pawl 102 is rotated toward the first substrate 20 and/or the heat sink 50 and positioned above the first substrate 20 and/or the heat sink 50, the fastener 15 is screwed so that the pawl 102 engages the first substrate 20 or the heat sink 50, thereby connecting and mounting the first substrate 20 to the second substrate 30. In this way, without using additional tools, the operator only needs to operate the fastener 15 and the pawl 102 of the locking member 10 to securely connect and mount the first substrate 20 to the second substrate 30.

Having thus described several aspects of several embodiments of a member for retaining and releasing a first circuit board to and from a second circuit board, it is to be appreciated that various alterations, modifications, and improvements will readily occur to those skilled in the art. Such alterations, modifications, and improvements are intended to be part of this disclosure, and are intended to be within the spirit and scope of the invention. While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

In the claims, as well as in the specification above, use of ordinal terms such as “first,” “second,” “third,” etc. does not by itself connote any priority, precedence, or order of one element over another or the temporal order in which acts of a method are performed, but are used merely as labels to distinguish one element having a certain name from another element having a same name (but for use of the ordinal term) to distinguish the elements.

What is claimed is:

1. A locking member configured for toolless securing a first substrate to a second substrate, the locking member comprising:
a supporting base configured to engage the second substrate;
a conductive cover rotatably coupled to the supporting base; and
a conductive beam comprising a plurality of protrusions configured to engage the first substrate, the plurality of protrusions comprising a first protrusion fixedly connected to the conductive cover and a second protrusion movable relative to the conductive cover.

2. The locking member of claim 1, wherein:
the first protrusion of the conductive beam protrudes from a lower surface of the conductive beam;
the conductive beam comprises a pair of grooves on an upper surface of the conductive beam facing away from the first protrusion, and a spacer between the pair of grooves;
the conductive cover comprises a pair of lugs disposed in the pair of grooves of the conductive beam; and
a connecting shaft extends through the pair of lugs of the conductive cover and the spacer of the conductive beam so as to fixedly connect the first protrusion to the conductive cover.

3. The locking member of claim 2, wherein:
the conductive cover is configured to rotate about the supporting base until the first protrusion and the second protrusion of the plurality of protrusions are disposed in corresponding positioning holes of the first substrate.

4. The locking member of claim 3, wherein:
the plurality of protrusions comprise at least two second protrusions on opposite sides of the first protrusion in a length direction of the conductive beam.

5. The locking member of claim 4, wherein:
the at least two second protrusions are symmetrically disposed on the opposite sides of the first protrusion.

6. The locking member of claim 5, wherein:
the first protrusion is located at a central portion of the conductive beam in the length direction of the conductive beam.

7. The locking member of claim 3, wherein:
the supporting base is a first supporting base; and
the locking member comprises a second supporting base configured to engage the second substrate at an other end of the conductive cover, and a fastener configured to extend through the second substrate, the second supporting base, and the conductive cover at the other end of the conductive cover.

8. The locking member of claim 1, wherein:
the first substrate is a compression attached memory module (CAMM).

9. A locking member configured for toolless securing a first substrate to a second substrate, the locking member comprising:
a positioner configured to engage the second substrate;
a pawl configured to engage the first substrate; and
an elastic member configured to couple the pawl to the positioner.

10. The locking member of claim 9, wherein:
the locking member comprises a fastener comprising a head engaging the pawl, a distal end configured to secure to the second substrate, and a shank between the head and the distal end, the shank configured to extend through the pawl, the elastic member, and the positioner.

11. The locking member of claim 10, wherein:
the positioner is configured to be positioned adjacent to an end of the first substrate in a length direction of the first substrate.

12. The locking member of claim 11, wherein:
the positioner comprises a hollow portion, and a seat;
the elastic member is disposed on the seat in the hollow portion; and
the pawl is disposed on the elastic member.

13. The locking member of claim 12, wherein:
the pawl comprises a first portion having a long side subportion and a short side subportion, and a second portion extending from the long side subportion of the first portion into the hollow portion of the positioner and configured to engage the elastic member, the short side subportion of the first portion configured to press the first substrate.

14. The locking member of claim 13, wherein:
the short side subportion of the first portion is configured to engage a heat sink disposed on the first substrate.

15. The locking member of claim 13, wherein:
the fastener is configured to cooperate with the elastic member so as to adjust a distance between the long side subportion of the first portion of the pawl and the positioner opposite to a first end as well as a distance between the short side subportion of the first portion of the pawl and the second substrate.

16. The locking member of claim 15, wherein:
the positioner comprises a positioning slot;
the second portion of the pawl comprises an extension protruding in a radial direction; and
the pawl is configured to rotate about the positioner until the extension of the second portion of the pawl is inserted into the positioning slot of the positioner.

17. The locking member of claim 16, wherein:
the positioner comprises a convex portion adjacent to the positioning slot and protruding toward the pawl so as to restrain an extent of rotation of the pawl.

18. An electronic system comprising:
the locking member of claim 9;
the first substrate;
the second substrate; and
a connector disposed between and connecting the first substrate and the second substrate.

19. The electronic system of claim 18, wherein:
the first substrate is a compression attached memory module (CAMM).

20. The electronic system of claim 18, comprising:
a backplate attached to the second substrate on a surface opposite the locking member.
